(19) United States
(12) Patent Application Publication
(10) Pub. No.: US 2026/0150751 A1
(43) Pub. Date: May 28, 2026

(54) 4D MODULAR VERTICAL CHIPLET PACKAGING

(71) Applicant: Intel Corporation, Santa Clara, CA (US)

(72) Inventors: Chia Chuan WU, Bayan Lepas (MY); Suan Ching CHEAH, Gelugor (MY); Timothy Kheng Kooi LIM, Georgetown (MY); Yee Hong TAN, Menglembu (MY); Bok Eng CHEAH, Gelugor (MY); Lee Fueng YAP, Gelugor (MY)

(21) Appl. No.: 18/956,064

(22) Filed: Nov. 22, 2024

(51) Int. Cl. H01L 25/18; H01L 23/00; H01L 23/06; H01L 23/08; H01L 23/29; H01L 23/31; H01L 23/373; H01L 25/00; H10B 80/00

(52) U.S. Cl. CPC H10W 90/00; H10B 80/00; H10W 40/258; H10W 74/131; H10W 74/473; H10W 76/17; H10W 76/18; H10W 70/09; H10W 70/60; H10W 70/6528; H10W 72/01221; H10W 90/10; H10W 90/724

(57) ABSTRACT

The present disclosure generally relates to a device including a substrate, a chip including a first chip surface and a bottom chip surface which is configured orthogonal to the first chip surface, wherein the chip includes sets of chiplets spaced apart from each other, wherein each set of chiplets includes a first surface and a bottom surface, and wherein chiplets in the sets of chiplets are vertically stacked to render the first surface parallel to the first chip surface and the bottom surface parallel to the bottom chip surface, a metal redistribution layer electrically coupled to the bottom chip surface; and solder bumps configured between the metal redistribution layer and the substrate to electrically couple the metal redistribution layer to the substrate. A method is also described.

### BACKGROUND

Traditionally, vertical stacking may be used to reduce the contact area between chiplets and a package substrate. FIG. 1 shows such an example, depicting traditionally packaged vertical stack chiplets. Consequently, the silicon bumps tend to be arranged closer to each other, resulting in a very fine pitch and a very limited input/output (I/O) breakout area. Additionally, with the introduction of four-dimensional (4D) packaging, the number of chiplets has significantly increased, which may lead to thermal dissipation challenges. Furthermore, each chiplet module may require an independent power delivery connection to the substrate, creating redundancy.

To address the above, constraints in real estate between vertically stacked chiplets and interconnects of a package substrate were addressed through interconnect pitch reductions (e.g., using smaller solder bump geometry) in one traditional approach. However, such reduction to the interconnect pitch and/or geometry tends to lead to undesirable surface mounting complexity and yield lost challenges. In another approach, power rails were merge at the package level for package pin count reduction. However, merging power rails at the package level may not resolve silicon bump redundancy.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 is a cross-sectional view of a traditional example of vertically stack chiplets packaging;

FIG. 2 shows a top view of a device of the present disclosure. The line A-A′ denotes for a cross-sectional view of the chip module, which is illustrated in more detail in FIG. 3;

FIG. 3 shows the cross-sectional view of an example of the device of the present disclosure that is shown in FIG. 2;

FIG. 4 shows a cross-sectional view of the device of FIG. 3. Specifically, FIG. 4 shows details of the contact pad and the active layer for one of the sets of chiplets in the device;

FIG. 5 shows a cross-sectional view of the device of FIG. 3, except that the device includes an additional thermally conductive layer;

FIG. 6 shows a cross-sectional view of the device of FIG. 3, except certain parts of the routing layer is merged to form a single power rail;

FIG. 7A is a schematic showing first few processes in a method of the present disclosure. The method may be a method for forming the device of the present disclosure;

FIG. 7B is a schematic showing the next few processes continuing from the method of FIG. 7A; and

FIG. 7C is a schematic showing the next few processes continuing from the method of FIG. 7B, completing the method to render the device.

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects may be combined with one or more other aspects to form new aspects.

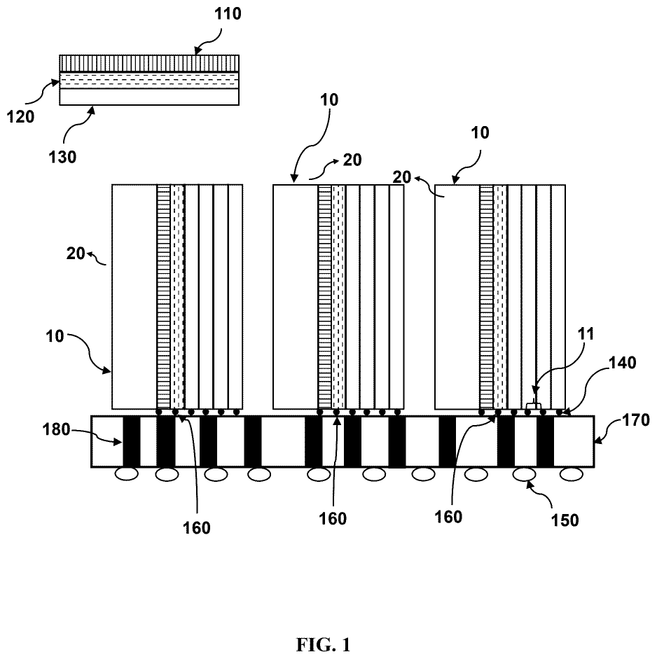

The present disclosure generally relates to a device. The device may help to address any of the issues and limitations mentioned above. For instance, the device may help to address any of the issues and limitations, for example, space constraints arising from a device housing a plurality of vertically stacked chiplets. The plurality of vertically stacked chiplets, in the present disclosure, may be referred to as sets of chiplets, and alternatively as chiplet modules, wherein each set of chiplets (each chiplet module) houses chiplets. Housing such sets or modules renders limited spaces for inputs and outputs connection to each of the sets, as the sets of chiplets occupy space in a device (such as a semiconductor device) already having limited real estate. For example, in 4D packaging, traditionally the coupling of a chiplet to a substrate (e.g., package substrate) may be through the active layer at the bottom surface (significantly reduced area), hence require much tighter/higher input/output (I/O) density at the active layer at the bottom surface (surface of chiplet proximal to the substrate). Higher I/O density may present manufacturing risk, such as unwanted solder bump bridging, rendering it difficult and challenging to accommodate input and output connections. An example of such problems is illustrated in FIG. 1.

FIG. 1 shows a traditional example (cross-sectional view) of vertically stack chiplets packaging. In FIG. 1, it can be seen that the silicon bumps 140 suffer from an undesirably fine pitch 11 and hence a limited input/output (I/O) breakout area. The fine pitch 11 shows the high I/O density at the active layer at the bottom surface. Moreover, with the vertical stacking, the number of chiplets increases considerably and each set of chiplets (i.e., chiplet modules) are packed closer, which may undesirably lead to poor thermal dissipation of heat 20 even with a thermal dissipation unit 10 (e.g., a heat spreader) coupled to each chiplet module. Also, each chiplet module may need an independent power delivery 130 connection to the substrate, which creates redundancy in terms of the power delivery unit 120 needed. The image shown in top left corner of FIG. 1 is a legend to denote different chiplets that may be configured in a set of chiplets. 110 denotes a processing unit (e.g., a processor or computing unit). 120 denotes a power delivery unit. 130 denotes a cache or a memory unit. 150 denotes a solder bump or a solder ball. 160 denotes power delivery connection. 170 denotes a substrate (e.g., a silicon substrate or a package substrate). The vertical structures in the substrate, one of which is denoted 180, refer to the metal routings or interconnects. The present device circumvents such problems and one or more limitations mentioned above.

Advantageously, the present device may have increased inputs and outputs (I/O) breakout areas via a metal redistribution layer (or termed herein as side redistribution layer). The metal redistribution layer may include copper metal interconnects, which may help expand a vertically stacked chiplet's connection to one or more solder bumps (or termed herein as solder balls) on a substrate (e.g., a package substrate).

Advantageously, the present device may help in reducing manufacturing cost and complexity by avoiding fine pitch surface mounting implementation. The metal redistribution line in the present device allows connection of a vertically stacked chiplet to a package substrate assembly using wider bump pitch.

Advantageously, the present device confers improved I/O density through a shared power rail (i.e., a routing layer) in the metal redistribution layer, and helps reduce the count of dedicated power bumps for the vertically stacked chiplets.

Further advantageously, the present device provides improved thermal dissipation of the vertically stacked chiplets through a thermally conductive frame, e.g., a metal frame or a silicon substrate in contact with each set of vertically stacked chiplets and a thermal dissipation unit (or termed herein as heat spreader).

In general, the device of the present disclosure may be, for example, an electronic package. The device may include one or more vertically stacked chiplets (VSC) that electrically connect to a substrate (e.g., a package substrate) via a metal redistribution layer (abbreviated RDL). The RDL may distribute a signal from one or more vertical chiplet contact pad (finer pitch) to a contact pad (larger pitch) in the substrate, wherein the RDL may be electrically coupled to the substrate. The vertically stacked chiplets may be at least partially embedded in a frame. The frame may include or may be formed of an organic material, a glass, silicon, and/or a metal.

The present disclosure also describes a method. The method may be a method for forming the device. It follows that the method may help to address and/or circumvent any of the issues and limitations mentioned above.

To more readily understand and put into practical effect the present disclosure, the device and method, and particular aspects will now be described by way of examples and not limitations, and with reference to the drawings. For the sake of brevity, duplicate descriptions of features and properties may be omitted.

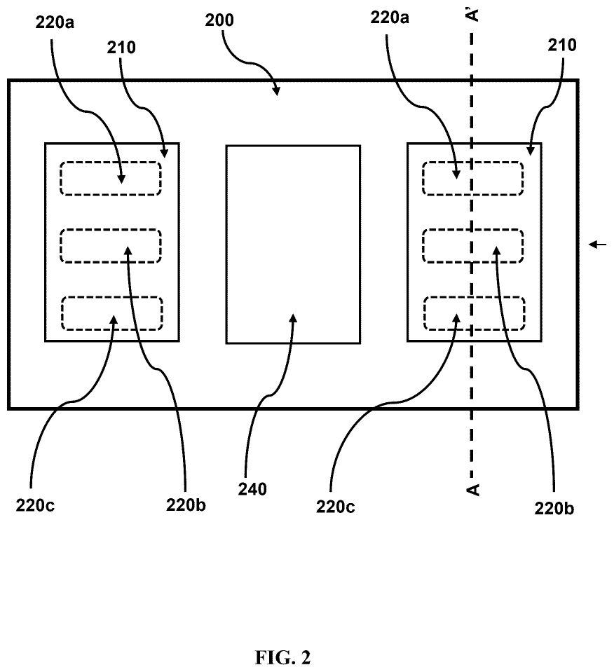

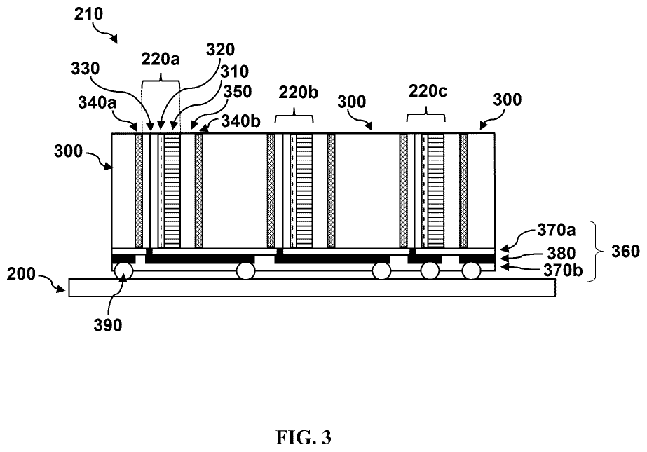

FIG. 2 shows a top view of a device of the present disclosure. The device includes a substrate 200 having a chip module 210 (or termed modular chiplets) thereon. The chip module 210 may be referred to as a chip 210 for brevity. The chip 210 may include sets of chiplets 220a, 220b, 220c, i.e., each set including chiplets 220a, 220b, 220c. Each chip may have a metal redistribution layer (not shown). 240 denotes a processing unit (e.g., central processing unit, a graphic processing unit, a tensor processing unit, a digital signal processor, a tensor processing unit, or a neural network processing unit). The line A-A′ denotes for a cross-sectional view of the chip 210, which is illustrated in more detail in FIG. 3.

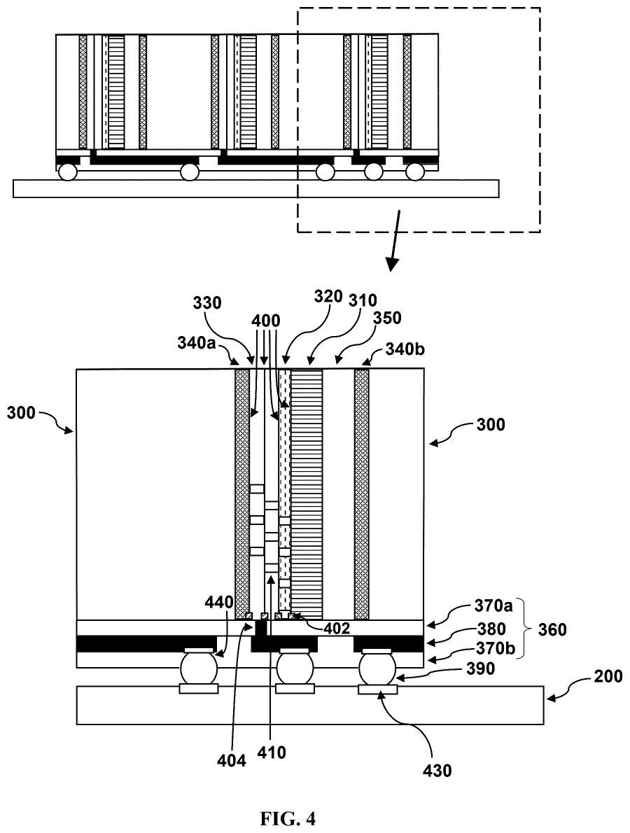

FIG. 3 shows the cross-sectional view of an example of the device of the present disclosure that is shown in FIG. 2. FIG. 3 shows the device (e.g., an electronic package) having a chip 210 configured with sets of chiplets 220a, 220b, 220c, wherein each set of chiplets 220a, 220b, 220c include chiplets that are vertically stacked. The device having such architecture, including the other features mentioned above, is advantageous in that the device has improved performance and desirable device miniaturization. In various examples, the chip 210, or each set of chiplets 220a, 220b, 220c, may be configured as a central processing unit (CPU), a graphic processing unit (GPU), a neural network processing unit (NPU), a tensor processing unit (TPU), a graphic processing unit (GPU), a high-bandwidth memory (HBM) unit, or a digital signal processing unit. In various examples, the chip 210 may include a first chip surface and a bottom chip surface orthogonal to the first chip surface. In various examples, each set of chiplets 220a, 220b, 220c may have a first surface parallel to the first chip surface. In various examples, each set of chiplets 220a, 220b, 220c may have a bottom surface parallel to the bottom chip surface, wherein the bottom surface is orthogonal to the first surface. In various examples, each set of chiplets 220a, 220b, 220c may have an active layer (see FIG. 4 reference numeral 400) configured proximal to the first surface. 300 denotes the frame (e.g., a metal frame, a silicon frame, or a mold frame), 310 denotes a processing (e.g., a computing) chiplet, such a computing chiplet may be an arithmetic logic unit. 320 denotes power delivery chiplet (e.g., a voltage regulator). 330 denotes a cache or memory chiplet. 340a, 340b each denotes an epoxy layer. 350 denotes a thermal dissipation unit (i.e., heat spreader). 360 denotes the metal redistribution layer (RDL) which includes two dielectric layers 370a, 370b sandwiching the routing layer 380. 390 denotes a solder bump (i.e., a solder ball 390). 200 denotes the substrate (e.g., a package substrate).

FIG. 4 shows a cross-sectional view of the device of FIG. 3 (for brevity and not to convolute the figure, and given the other components are the same, the reference numerals are not repeated in the figure). Specifically, FIG. 4 shows details of the contact pad and the active layer for one of the sets of chiplets in the device. Referring to FIG. 4, the active layer 400 may include at least one or more transceivers, e.g., a transistor gate and a metal layer. In various examples, the active layer may include one or more side contact pads (see FIG. 4, reference numeral 402). In various examples, the one or more side contact pads 402 (for brevity may be referred to as contact pads 402) may be configured proximal to the bottom surface. In various examples, the active layer 400 may be coupled to the metal redistribution layer (RDL) 360 through the one or more side contact pads 402. In various examples, the one or more side contact pads 402 may be coupled to the RDL 360 through contact via 404. In various examples, as shown in FIG. 4, a first chiplet of one set of chiplets is electrically coupled to a second chiplet via one or more vias 410 (e.g., through silicon vias as shown in bottom image of FIG. 4) to form a set of vertically stacked chiplets. In various examples, each set of vertically stacked chiplets include a first surface in parallel to the first chip surface. In various examples, chip may have a bottom chip surface orthogonal to the first chip surface. In various examples, the bottom surface of each set of chiplets is configured parallel to the bottom chip surface of the chip. In various examples, there may be a metal layer electrically coupled to the bottom surface and bottom chip surface. In various examples, the metal redistribution layer 360 may include one or more micro-vias 404 and one or more metal layers 380, wherein the metal redistribution layer 360 may be coupled to the plurality of side contact pads 402 at the bottom surface. In various examples, the metal redistribution layer may include contact pads 440 at the routing layer 380 configured opposite to the side contact pads 402. In various examples, the side contact pads 402 may have a first pitch geometry ranging from 5 μm to 50 μm. In various examples, the contact pads 440 of the routing layer may include a second pitch geometry ranging from 100 μm to 300 μm. In various examples, the solder bump 390 may be coupled to the substrate 200 through substrate contact pad 430. In various examples, the modular chip may be at least partially surrounded by a frame 300. In various examples, the frame 300 may include an epoxy resin with silica filler, a polyester resin, a polyethylene or a polypropylene. In various examples, the frame 300 may include a glass substrate, a silicon substrate or a metal frame. In various examples, each set of chiplet may be directly coupled to the frame 300 at the first surface. In various examples, each set of chiplets may be isolated from the frame 300 by epoxy layers 340a, 340b. In various examples, the epoxy layers 340a, 340b may include a thermally conductive filler. e.g., graphite, silver, or a silver composite particle. In various examples, the chip may include a first set of chiplets and a second set of chiplets, wherein the first set of chiplets is isolated from the second set of chiplets by the frame 300. In various examples, a thermal heat spreader, e.g., an aluminum sheet, a graphene sheet, a thermal pad, or a thermal adhesive film, may be configured between the frame and each set of chiplet at the second surface (which is parallel and opposite to the first surface, proximal to a computing chiplet).

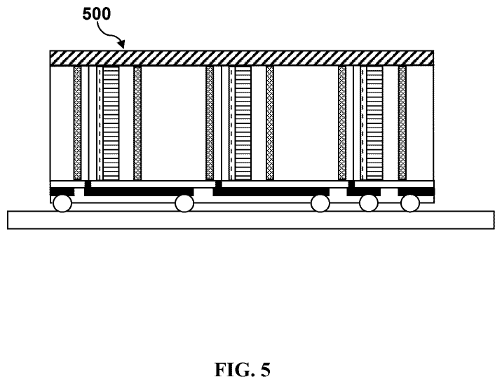

FIG. 5 shows a cross-sectional view of the device of FIG. 3 (for brevity and not to convolute the figure, and given the other components are the same, the reference numerals are not repeated in the figure), except that the device additionally includes a thermally conductive layer 500, which aids in heat dissipation from the chiplets and the chip. In various examples, the thermally conductive layer 500 may be, for example, a copper layer, which may extend over a top surface, wherein the top surface is opposite and parallel to the bottom surface.

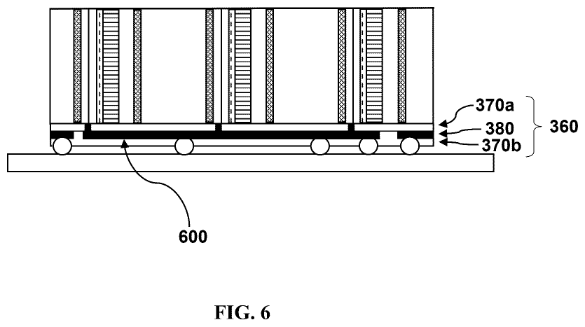

FIG. 6 shows a cross-sectional view of the device of FIG. 3 (for brevity and not to convolute the figure, and given the other components are the same, the reference numerals are not repeated in the figure), except certain parts of the routing layer is merged to form a single power rail 600. The power rail 600 advantageously reduces the number of silicon and/or package bumps needed in traditional devices, allowing saving space. In various examples, the power planes for the respective first, second and third sets of chiplets may be merged at the metal redistribution layer 360 (e.g., at the routing layer 380) to minimize the required silicon and/or package solder bump. Reduced silicon and/or package solder bump for power rails allows more compact package foot-print for device miniaturization.

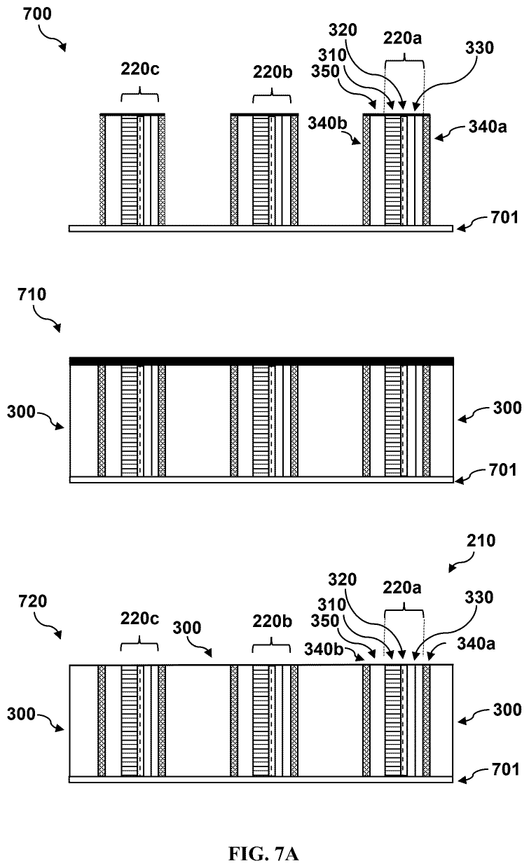

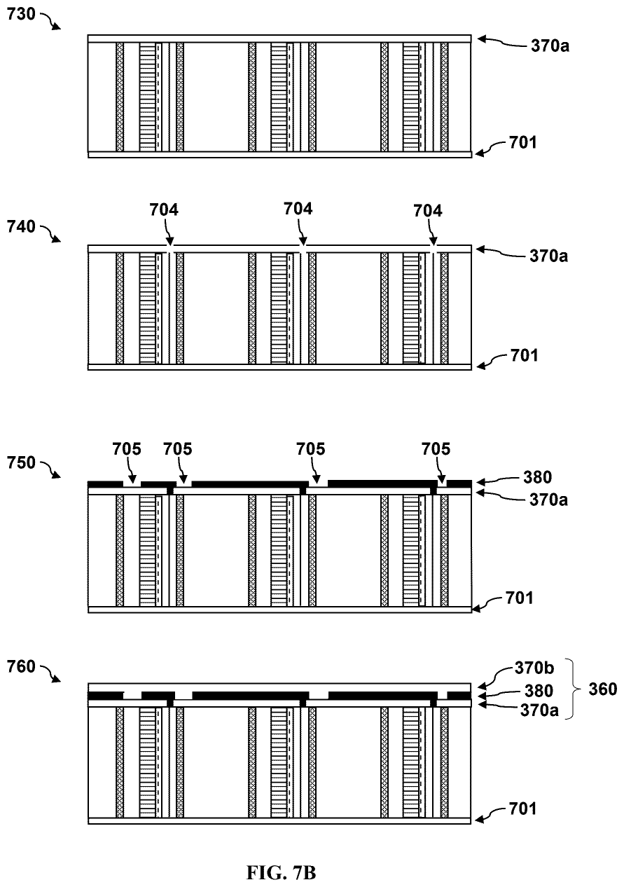

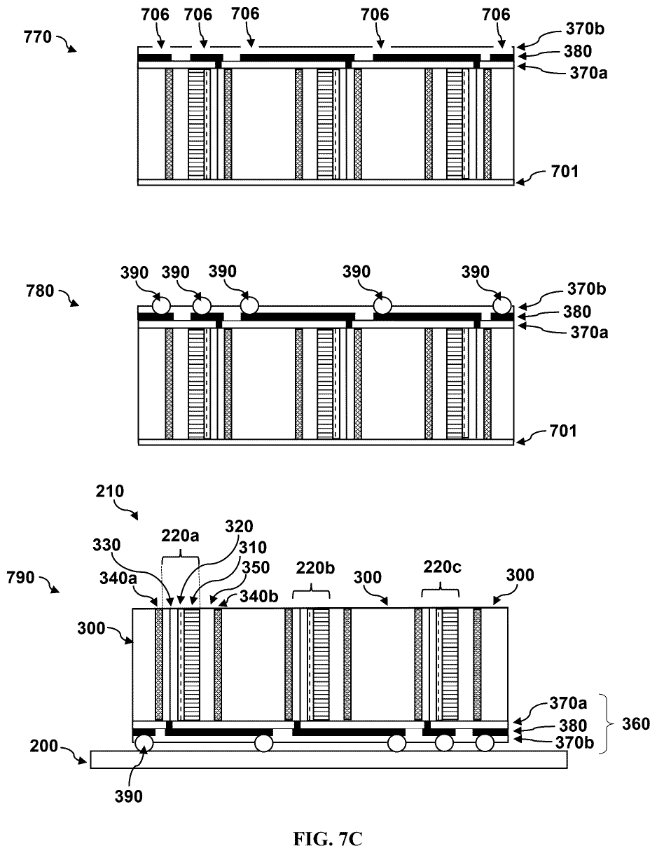

FIG. 7A is a schematic showing first few processes in a method of the present disclosure. The method may be a method for forming the device of the present disclosure. The method may involve forming 700 the sets of chiplets 220 a, 220 b, 220 c on a carrier 701. This may be carried out by attaching the chiplets 220a, 220b, 220c to the carrier 701 via a suitable process that may be known, for example, hot press or lamination in a manner that allows the chiplets 220 a, 220 b, 220 c to be vertically stacked. The method may involve forming 710 the frame 300 to accommodate the sets of chiplets (reference numerals are not repeated for brevity and not to convolute the figure). This may be carried out via compression, a transfer process, or an injection molding process. The method may involve mechanical grinding to remove 720 parts of the frame 300, exposing parts of the chip and parts of each set of chiplets 220a, 220b, 220c, at the surface opposite to and distal from the carrier 701.

FIG. 7B is a schematic showing the next few processes continuing from the method of FIG. 7A. The method may involve forming 730 a dielectric layer 370 a on the chip surface and/or the surface of each set of chiplets (reference numerals are not repeated for brevity and not to convolute the figure) that are exposed (the surface that is opposite to and distal from the carrier 701). The method may involve removing 740 a portion of the dielectric layer 370a to form openings 704. This may be carried out by any suitable known processes, e.g., laser drilling process. The method may involve forming 750 a routing layer 380 on the dielectric layer 370a via, for example, electroplating (and an etching process may be involved to form depressions 705 in the routing layer 380). The method may involve forming 760 another dielectric layer 370b on the routing layer 380. This may be carried out by any suitable known processes, e.g., hot press or lamination.

FIG. 7C is a schematic showing the next few processes continuing from the method of FIG. 7B, completing the method to render the device. The method may involve removing 770 a portion of the dielectric layer 370 b formed on the routing layer 380, for example, through laser drilling process. This is to render openings 706 to fit solder balls 390 (i.e., solder bumps) on the contact pad (not shown), for example, on the routing layer 380. The method may involve forming 780 the solder balls 390 on the contact pad that is on the routing layer 380. The method may involve transferring 790 the frame with the set of chiplets 220 a, 220b, 220c having the metal redistribution layer 360 (i.e., the routing layer 380 sandwiched by two dielectric layers 370a, 370b) from the carrier (not shown) onto a substrate 200 (e.g., a package substrate). The method advantageously allows for increased I/O breakout area and shared power among chiplet modules. The sequence or order of processes in the method may be interchangeable, where suitable to do so.

Additional aspects of the disclosure are demonstrated by way of non-limiting examples below.

Example 1 may include a device. In various aspects and examples, the device may include a substrate, a chip including a first chip surface and a bottom chip surface which may be configured orthogonal to the first chip surface, wherein the chip may include sets of chiplets spaced apart from each other, wherein each set of chiplets may include a first surface and a bottom surface, and wherein chiplets in the sets of chiplets may be vertically stacked to render the first surface parallel to the first chip surface and the bottom surface parallel to the bottom chip surface, a metal redistribution layer electrically coupled to the bottom chip surface, and solder bumps (i.e., solder balls) configured between the metal redistribution layer and the substrate to electrically couple the metal redistribution layer to the substrate.

Example 2 may include the device of example 1 and/or any other example disclosed herein, further including a frame which may accommodate the chip in a manner which at least partially covers the chip and isolates one set of chiplets from another set of chiplets.

Example 3 may include the device of example 2 and/or any other example disclosed herein, wherein a top chip surface of the chip and a top surface of each set of chiplets may be exposed, wherein the top chip surface and the top surface may be opposite to the bottom chip surface and the bottom surface, respectively.

Example 4 may include the device of example 2 and/or any other example disclosed herein, wherein the frame may include an organic material, glass, silicon, or a metal.

Example 5 may include the device of example 2 and/or any other example disclosed herein, wherein each set of chiplets may include a second surface opposite to the first surface, wherein each set of chiplets may be isolated from the frame by a pair of epoxy layers, wherein one epoxy layer may be adjacent to the frame and proximal to the first surface and the other epoxy layer may be adjacent to the frame and proximal to the second surface.

Example 6 may include the device of example 5 and/or any other example disclosed herein, wherein each set of chiplets may include a thermal dissipation unit configured between the second surface and the epoxy layer proximal to the second surface.

Example 7 may include the method of example 6 and/or any other example disclosed herein, further comprising, in each set of chiplets, a processing unit configured adjacent to the thermal dissipation unit, a power delivery unit configured adjacent to and distal from the thermal dissipation unit, and one or more memory units configured proximal to the power delivery unit and distal from the thermal dissipation unit.

Example 8 may include the device of example 7 and/or any other example disclosed herein, further including a via in the power delivery unit and/or a via in each of the one or more memory units, wherein the via in the power delivery unit may extend horizontally across the power delivery unit and/or the via in each of the one or more memory units may extend horizontally across in each of the one or more memory units, wherein the via may electrically couple the power delivery unit and the one or more memory units.

Example 9 may include the device of example 7 and/or any other example disclosed herein, wherein an active layer is configured between (i) the first surface and the first chip surface, wherein the active layer may be adjacent to and in contact with the first surface, and/or (ii) two memory units, wherein the active layer may be adjacent to and in contact with the two memory units, and/or (iii) one memory unit and the power delivery unit, wherein the active layer may be adjacent to and in contact with the one memory unit and the power delivery unit, and (iv) the power delivery unit and the processing unit, wherein the active layer may be adjacent to and in contact with the power delivery unit and the processing unit. In various examples, each chiplet in a set of chiplets may have its respective active layer (and also may include, for example, transistor and a metallization layer (e.g., tungsten or copper layers insulated by polyimide layers)). The active layer may be configured on one vertical surface of the chiplet, e.g., the active layer of the first chiplet (e.g., nearest to the first chip surface) may be configured on the first chiplet's first surface (a vertical surface of the first chiplet that is nearest to the first chip surface), and this active layer may be electrically coupled to an active layer of an adjacent chiplet (i.e., the second chiplet, wherein the active layer is configured on the second chiplet's first surface (a vertical surface of the second chiplet that is nearest to the first chip surface)) through one or more through silicon vias (TSVs).

Example 10 may include the device of example 1 and/or any other example disclosed herein, wherein the active layer may include at least a transistor electrically coupled to one or more metallization layers, wherein the one or more metallization layers each may include copper or tungsten, and wherein the one or more metallization layers are isolated by a dielectric material. The one or more metallization layers allow signals to be relayed to and from the at least one transistor. The dielectric material may be configured in a manner that isolates the one or more metallization layers from any undesirable electrical contact. In various examples, the active layer may include copper, silicon, or tungsten.

Example 11 may include the device of example 9 and/or any other example disclosed herein, wherein the metal redistribution layer may include a routing layer sandwiched between two dielectric layers, wherein one dielectric layer may be in contact with the bottom surface and the other dielectric layer may be configured proximal to the substrate and in contact with the solder bumps.

Example 12 may include the device of example 11 and/or any other example disclosed herein, wherein the metal redistribution layer may include a side contact pad which may be in contact with the active layer and electrically coupled to the routing layer.

Example 13 may include the device of example 11 and/or any other example disclosed herein, wherein the metal redistribution layer may include a contact pad in contact with one solder bump, wherein the contact pad may be configured along the routing layer and proximal to the substrate.

Example 14 may include the device of example 1 and/or any other example disclosed herein, wherein the substrate may include a substrate contact pad which one solder bump may be configured on and in contact with.

Example 15 may include the device of example 1 and/or any other example disclosed herein, further including a thermally conductive layer configured on the top chip surface and in contact with the top surface of one or more sets of chiplets.

Example 16 may include the device of example 1 and/or any other example disclosed herein, wherein each set of chiplets may be configured as a central processing unit, a graphic processing unit, a neural network processing unit, a tensor processing unit, or a high-bandwidth memory unit.

Example 17 may include a method of the present disclosure. The method may include forming vertically stacked sets of chiplets spaced apart from each other on a carrier to render each set of chiplets a first surface and a bottom surface orthogonal to the first surface for forming a chip, forming a metal redistribution layer proximal to the bottom surface, forming solder bumps on the metal redistribution layer, and transferring the vertically stacked sets of chiplets with the metal redistribution layer and the solder bumps onto a substrate from the carrier, wherein the solder bump may be configured between the metal redistribution layer and the substrate to electrically couple the metal redistribution layer to the substrate.

Example 18 may include the method of example 17 and/or any other example disclosed herein, further including forming a frame which may accommodate the chip in a manner which may at least partially cover the chip and isolate one set of chiplets from another set of chiplets.

Example 19 may include the method of example 17 and/or any other example disclosed herein, wherein forming the metal redistribution layer may include forming a dielectric layer adjacent to and in contact with the bottom surface, and forming a routing layer on and in contact with the dielectric layer prior to forming another dielectric layer, which may be on and in contact with the routing layer and proximal to the substrate, wherein the routing layer may be sandwiched between two dielectric layers.

Example 20 may include the method of example 19 and/or any other example disclosed herein, wherein forming the solder bumps on the metal redistribution layer may include removing a portion of the dielectric layer on and in contact with the routing layer and which may be proximal to the substrate, forming a contact pad on the routing layer at the portion of the dielectric layer which may be removed, and forming one solder bump in contact with the contact pad to electrically couple the metal redistribution layer to the substrate.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

While the present disclosure has been particularly shown and described with reference to specific aspects, it should be understood by persons skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
a substrate;
a chip comprising a first chip surface and a bottom chip surface which is configured orthogonally to the first chip surface, wherein the chip comprises sets of chiplets spaced apart from each other, wherein each set of chiplets comprises a first surface and a bottom surface, and wherein chiplets in the sets of chiplets are vertically stacked to render the first surface parallel to the first chip surface and the bottom surface parallel to the bottom chip surface;
a metal redistribution layer electrically coupled to the bottom chip surface; and
solder bumps configured between the metal redistribution layer and the substrate to electrically couple the metal redistribution layer to the substrate.

2. The device of claim 1, further comprising a frame which accommodates the chip in a manner which at least partially covers the chip and isolates one set of chiplets from another set of chiplets.

3. The device of claim 2, wherein a top chip surface of the chip and a top surface of each set of chiplets are exposed, wherein the top chip surface and the top surface are opposite to the bottom chip surface and the bottom surface, respectively.

4. The device of claim 2, wherein the frame comprises an organic material, glass, silicon, or a metal.

5. The device of claim 2, wherein each set of chiplets comprises a second surface opposite to the first surface, wherein each set of chiplets is isolated from the frame by a pair of epoxy layers, wherein one epoxy layer is adjacent to the frame and proximal to the first surface and the other epoxy layer is adjacent to the frame and proximal to the second surface.

6. The device of claim 5, wherein each set of chiplets comprises a thermal dissipation unit configured between the second surface and the epoxy layer proximal to the second surface.

7. The device of claim 6, further comprising, in each set of chiplets, a processing unit configured adjacent to the thermal dissipation unit, a power delivery unit configured adjacent to and distal from the thermal dissipation unit, and one or more memory units configured proximal to the power delivery unit and distal from the thermal dissipation unit.

8. The device of claim 7, further comprising a via in the power delivery unit and/or a via in each of the one or more memory units, wherein the via in the power delivery unit extends horizontally across the power delivery unit and/or the via in each of the one or more memory units extends horizontally across in each of the one or more memory units, wherein the via electrically couples the power delivery unit and the one or more memory units.

9. The device of claim 7, wherein an active layer is configured between:
(i) the first surface and the first chip surface, wherein the active layer is adjacent to and in contact with the first surface; and
(ii) two memory units, wherein the active layer is adjacent to and in contact with the two memory units; and
(iii) one memory unit and the power delivery unit, wherein the active layer is adjacent to and in contact with the one memory unit and the power delivery unit; and
(iv) the power delivery unit and the processing unit, wherein the active layer is adjacent to and in contact with the power delivery unit and the processing unit.

10. The device of claim 9, wherein the active layer comprises at least a transistor electrically coupled to one or more metallization layers, wherein the one or more metallization layers each comprises copper or tungsten, and wherein the one or more metallization layers are isolated by a dielectric material.

11. The device of claim 9, wherein the metal redistribution layer comprises a routing layer sandwiched between two dielectric layers, wherein one dielectric layer is in contact with the bottom surface and the other dielectric layer is configured proximal to the substrate and in contact with the solder bumps.

12. The device of claim 11, wherein the metal redistribution layer comprises a side contact pad which is in contact with the active layer and electrically coupled to the routing layer.

13. The device of claim 11, wherein the metal redistribution layer comprises a contact pad in contact with one solder bump, wherein the contact pad is configured along the routing layer and proximal to the substrate.

14. The device of claim 1, wherein the substrate comprises a substrate contact pad which one solder bump is configured on and in contact with.

15. The device of claim 3, further comprising a thermally conductive layer configured on the top chip surface and in contact with the top surface of one or more sets of chiplets.

16. The device of claim 1, wherein each set of chiplets is configured as a central processing unit, a graphic processing unit, a neural network processing unit, a tensor processing unit, or a high-bandwidth memory unit.

17. A method comprising:
forming vertically stacked sets of chiplets spaced apart from each other on a carrier to render each set of chiplets a first surface and a bottom surface orthogonal to the first surface for forming a chip;
forming a metal redistribution layer proximal to the bottom surface;
forming solder bumps on the metal redistribution layer; and
transferring the vertically stacked sets of chiplets with the metal redistribution layer and the solder bumps onto a substrate from the carrier, wherein the solder bump is configured between the metal redistribution layer and the substrate to electrically couple the metal redistribution layer to the substrate.

18. The method of claim 17, further comprising forming a frame which accommodates the chip in a manner which at least partially covers the chip and isolates one set of chiplets from another set of chiplets.

19. The method of claim 17, wherein forming the metal redistribution layer comprises:
forming a dielectric layer adjacent to and in contact with the bottom surface; and
forming a routing layer on and in contact with the dielectric layer prior to forming another dielectric layer, which is to be on and in contact with the routing layer and proximal to the substrate, wherein the routing layer is sandwiched between two dielectric layers.

20. The method of claim 19, wherein forming the solder bumps on the metal redistribution layer comprises:
removing a portion of the dielectric layer on and in contact with the routing layer and which is to be proximal to the substrate;
forming a contact pad on the routing layer at the portion of the dielectric layer which is removed; and
forming one solder bump in contact with the contact pad to electrically couple the metal redistribution layer to the substrate.
